(19) United States
(12) Patent Application Publication
(10) Pub. No.: US 2013/0300492 A1
(43) Pub. Date: Nov. 14, 2013

(54) SWITCHING POWER CAPABLE OF AVOIDING COUPLING EFFECTS

(71) Applicants: Yu Zhao, Shenzhen (CN); Xiang Sun, Shenzhen (CN); Fei Wang, Guangzhou (CN); Dong Chen, Guangzhou (CN)

(72) Inventors: Yu Zhao, Shenzhen (CN); Xiang Sun, Shenzhen (CN); Fei Wang, Guangzhou (CN); Dong Chen, Guangzhou (CN)

(73) Assignee: NVIDIA CORPORATION, Santa Clara, CA (US)

(21) Appl. No.: 13/570,167

(22) Filed: Aug. 8, 2012

(30) Foreign Application Priority Data
May 14, 2012 (CN) 201210149580.1

(51) Int. Cl. H03K 17/687; H05K 13/00

(52) U.S. Cl. 327/434; 29/825

(57) ABSTRACT

A switching power capable of avoiding coupling effects is provided. The switching power comprises a driving loop. The driving loop comprises the substrate end and the gate end of a power Metal-Oxide-Semiconductor Field-Effect Transistor (MOSFET) and a controlling gate, and the controlling gate is connected to the gate end of the power MOSFET and the substrate end of the power MOSFET is connected to the controlling gate. The switching power provided by the present can avoid the coupling effect of the driving loop and the power stage loop at the common source pin, thereby reducing the switching power losses and improving the efficiency of the switching power.

### PRIORITY AND RELATED APPLICATION DATA

The present application claims the priority of Chinese Patent Application No. 201210149580.1, filed on May 14, 2012, which is incorporated herein by reference.

### FIELD

The present disclosure relates generally to a switching power, and particularly to a switching power capable of avoiding coupling effects.

### BACKGROUND

In the switching power of the prior art, power metal oxide semiconductor FETs (Metal-Oxide-Semiconductor Field-Effect Transistor, MOSFETs) are widely used in switching powers. A switching power comprises a driving loop and a power stage loop, both of wit. The driving loop charges or discharges the input capacitance of the power MOSFET, so as to switch the power MOSFET on or off. The power stage loop is the main path for large loading current generation. The driving loop and the power stage loop share the source pin of the power MOSFET, where the coupling effect occurs between the two loops. In particular, the switching loss increases significantly when there is large loading current.

FIG. 1 shows the circuit in a switching power 100 of the prior art. The figure shows the buck mode (the power voltage is higher than the output voltage mode). The power 100 comprises an input capacitor 107, a control gate 108, a MOSFET 105 and a MOSFET 109, an inductor 104, and an output capacitor 111. The figure also shows an equivalent resistance 106 and an equivalent resistance 110, a parasitic inductance101, a parasitic inductance 102, a parasitic inductance 103 and a parasitic inductance 112, wherein, the MOSFET 105 can be a power MOSFET. The switching power 100 converts the high DC voltage into low DC voltage by switching on or switching off of the power MOSFET105 and MOSFET 109, wherein, the driving loop 113 comprises the power MOSFET105, the equivalent resistance 106, the parasitic inductance 102 and the control gate 108 and the power stage loop 114 comprises the parasitic inductance 101, the power MOSFET105, the parasitic inductance102, the inductor 104 and the circuit load 115. As shown in the figure, the driving loop 113 and the power stage loop 114 share segment where the parasitic inductance 102 is.

When analyzing the coupling effect of the parasitic inductor 102 at the source, we found that the two loops shared the segment of the parasitic inductance 102. According to the formula dV=L_{coupled}*(dIₚₛₗ/dt), where L_{coupled} is the shared inductance, and Iₚₛₗ is the power stage loop current, the power stage loop would impact the drive loop so much because of the large dIpsl/dt (about 30 A/10 ns), so the switching loss would increase when increasing the loading current.

FIG. 2 shows the circuit in a boost mode (the power voltage is lower than the output voltage mode) switching power 200 of the prior art. The power 200 comprises an input capacitor 211, a control gate 208, a MOSFET 205 and a MOSFET 209, an inductor 204, and an output capacitor 207. The figure also shows an equivalent resistance 206 and an equivalent resistance 210, a parasitic inductance201, a parasitic inductance 202, a parasitic inductance 203 and a parasitic inductance 212, wherein, the MOSFET 205 can be a power MOSFET. The switching power 200 converts the low DC voltage into high DC voltage by switching on or switching off of the power MOSFET 205 and MOSFET 209, wherein, the driving loop comprises the power MOSFET205, the equivalent resistance 206, the parasitic inductance 202 and the control gate 208 and the power stage loop comprises the parasitic inductance 201, the power MOSFET 205, the parasitic inductance 202, the inductor 204 and the circuit load 215. As shown in the figure, the driving loop and the power stage loop share segment where the parasitic inductance 202 is. Similar to the buck mode switching power 100 in FIG. 1, there is also a coupling effect at the source of the parasitic inductance 202 in the boost mode switching power 200, which also causes large switching power loss.

Therefore, there is a need for improving the circuit structure of the power MOSFET packages in the prior art, so as to avoid the coupling effect at the common source pin of the driving loop and power stage loop in the switching power, thereby reducing the switching power loss and improving power efficiency.

### SUMMARY OF THE INVENTION

The present invention is related to a switching power capable of avoiding coupling effects. The switching power comprises a driving loop, wherein, the driving loop comprises the substrate end and the gate end of a power Metal-Oxide-Semiconductor Field-Effect Transistor (MOSFET) and a controlling gate, and the controlling gate is connected to the gate end of the power MOSFET and the substrate end of the power MOSFET is connected to the controlling gate.

Preferably, the switching power comprises a power stage loop, and the power stage loop comprises the drain end and the source end of the power MOSFET.

Preferably, the power MOSFET comprises a plurality of MOSFETs.

Preferably, the substrate ends of the plurality of MOSFETs are connected and comprise a separate substrate end of the power MOSFET.

Preferably, the plurality of MOSFETs is connected in parallel.

Preferably, the number the plurality of MOSFETs is two.

Preferably, the number the plurality of MOSFETs is three.

Preferably, the working mode of the switching power is buck mode.

Preferably, the working mode of the switching power is boost mode.

In another aspect of the invention, a manufacturing method for a switching power is also provided. The switching power comprises a driving loop, wherein, the driving loop comprises the substrate end and the gate end of a power Metal-Oxide-Semiconductor Field-Effect Transistor (MOSFET) and a controlling gate, and the controlling gate is connected to the gate end of the power MOSFET and the substrate end of the power MOSFET is connected to the controlling gate.

Preferably, the switching power comprises a power stage loop, and the power stage loop comprises the drain end and the source end of the power MOSFET.

Preferably, the power MOSFET comprises a plurality of MOSFETs.

Preferably, the substrate ends of the plurality of MOSFETs are connected and comprise a separate substrate end of the power MOSFET.

Preferably, the plurality of MOSFETs is connected in parallel.

Preferably, the number the plurality of MOSFETs is two.

Preferably, the number the plurality of MOSFETs is three.

Preferably, the working mode of the switching power is buck mode.

Preferably, the working mode of the switching power is boost mode.

The power MOSFET chip provided by the present invention and the switching power using the power MOSFET provided by the present can avoid the coupling effect of the driving loop and the power stage loop at the common source pin, thereby reducing the switching power losses and improving the efficiency of the switching power.

Additional features and advantages of the invention will be set forth in the description that follows, and in part will be apparent from the description, or may be learned by practice of the invention. The advantages of the invention will be realized and attained by the structure particularly pointed out in the written description and claims hereof as well as the appended drawings. It is to be understood that both the foregoing general description and the following detailed description are exemplary and explanatory and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 shows the circuit in a buck mode switching power of the prior art;

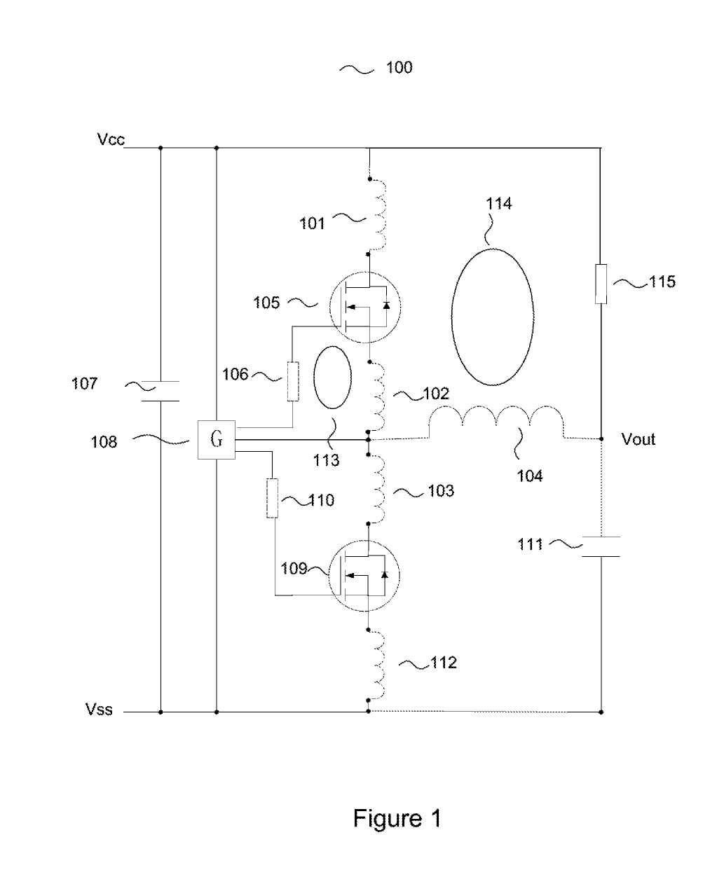

FIG. 2 shows the circuit in a boost switching power of the prior art:

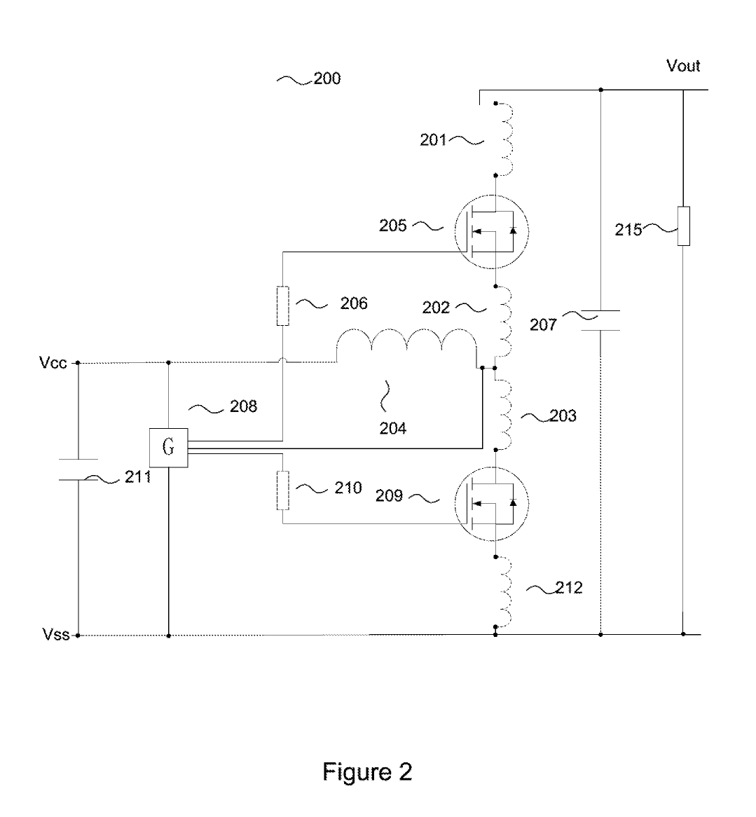

FIG. 3 shows the internal structure of the power MOSFET chip according to an exemplary embodiment of the invention;

FIG. 4 shows the internal structure of the power MOSFET chip according to one exemplary embodiment of the invention;

FIG. 5 shows the circuit in a buck mode switching power using a power MOSFET chip provided by the present invention; and

FIG. 6 shows the circuit in a boost mode switching power using the power MOSFET chip provided by the present invention.

### DETAILED DESCRIPTION

Example embodiments are described herein in the context of a switching power capable of avoiding coupling effects. Those of ordinary skill in the art will realize that the following description is illustrative only and is not intended to be in any way limiting. Other embodiments will readily suggest themselves to those skilled in the art having the benefit of this disclosure. Reference will now be made in detail to implementations of the example embodiments as illustrated in the accompanying drawings. The same reference indicators will be used to the extent possible throughout the drawings and the following description to refer to the same or like items.

Reference will now be made in detail to the preferred embodiments of the present invention, examples of which are illustrated in the accompanying drawings.

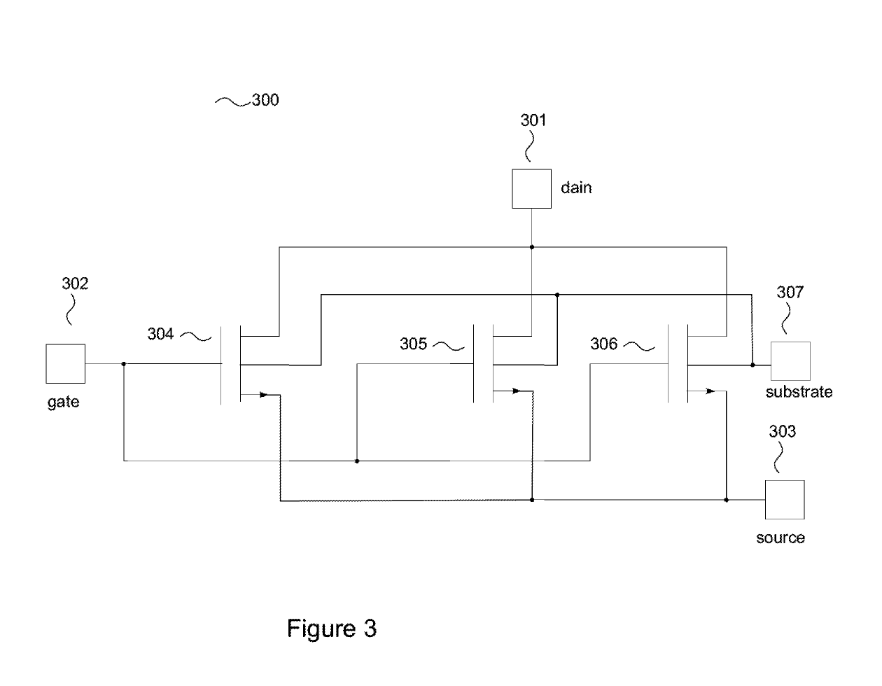

For the above mentioned power loss problem in the switching power of the prior art, the present invention improves the structure of the power MOSFET chip in a switching power according to one embodiment of the present invention. FIG. 3 shows the internal structure of the power MOSFET chip 300 provided by the present invention. As shown in the figure, there are multiple independent MOSFETs in the power MOSFET chip, such as MOSFET304, MOSFET305, MOSFET306, etc. They are connected in parallel. In one embodiment of the present invention, the substrate ends of the multiple MOSFETs, such as MOSFET304, MOSFET305, MOSFET306 and so on, are connected and pulled out independently as a separate substrate end 307 so that the power MOSFET chip 300 has a four-end structure, including a drain end 301, a gate end 302, a source end 303 and a substrate end 307. In this case, in such a switching power, the gate end and the substrate end are included in the driving loop. Then the driving loop is separate from the power stage loop, which comprises the source end, so that the coupling effect is avoided. In this way, the switching characteristics of the power MOSFET are improved and the coupling phenomena in switching power and the coupling characteristics of the power MOSFET chip are eliminated.

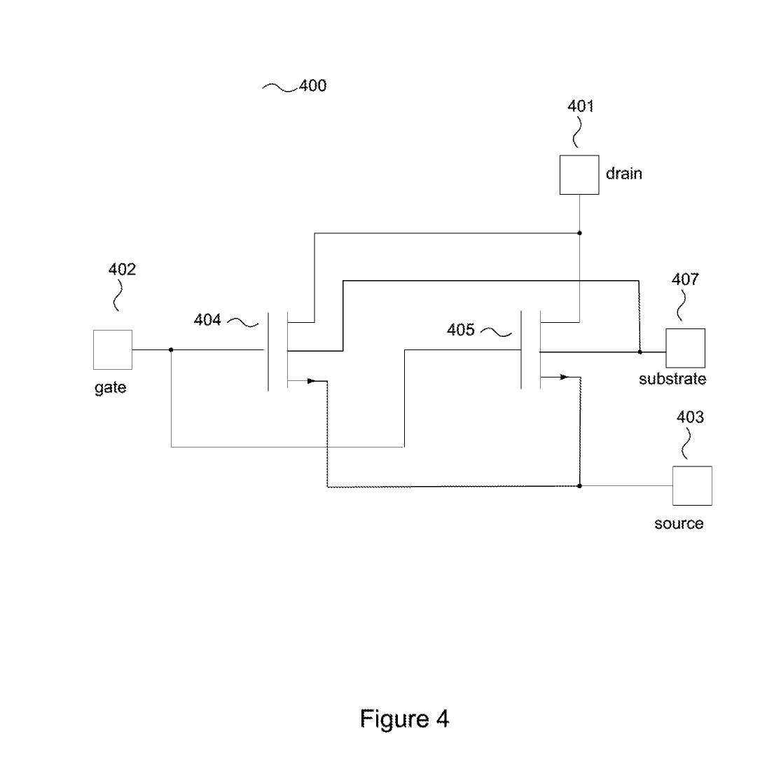

FIG. 4 shows the internal structure of the power MOSFET chip 400 provided by the present invention. As shown in the figure, there are two independent MOSFETs in the power MOSFET chip, namely MOSFET404 and MOSFET405. They are connected in parallel. In one embodiment of the present invention, the substrate ends of the two MOSFETs, such as MOSFET404 and MOSFET405, are connected and pulled out independently as a separate substrate end 407 so that the power MOSFET chip 400 has a four-end structure, including a drain end 401, a gate end 402, a source end 403 and a substrate end 407. Similarly, the above mentioned method is also applicable to the power MOSFET chips which have four or more independent MOSFETs connected in parallel in their internal structural, so that the internal structure of the power MOSFET chip is improved by pulling out the substrate end independently. In this case, in a switching power with such a power MOSFET chip, the gate end and the substrate end are included in the driving loop. Then the driving loop is separate from the power stage loop, which comprises the source end, so that the coupling effect is avoided. In this way, the switching characteristics of the power MOSFET are improved and the coupling phenomena in switching power and the coupling characteristics of the power MOSFET chip are eliminated.

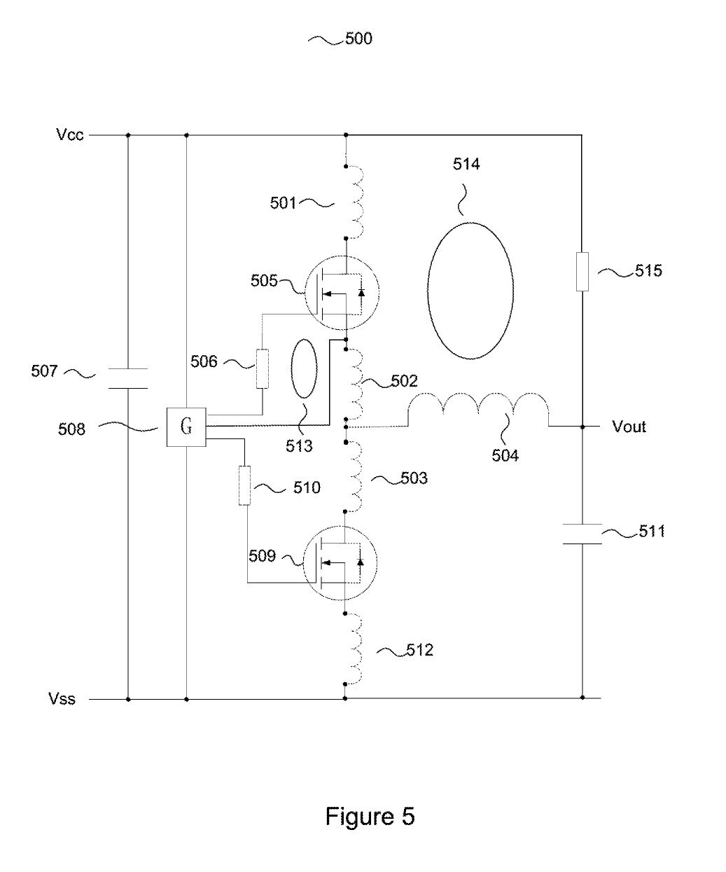

FIG. 5 shows the circuit in a switching power 500 using the power MOSFET chip provided by the present invention. The figure shows the buck mode (the power voltage is higher than the output voltage mode). The power 500 comprises an input capacitor 507, a control gate 508, a MOSFET 505 and a MOSFET 509, an inductor 504, and an output capacitor 511. The figure also shows an equivalent resistance 506 and an equivalent resistance 510, a parasitic inductance501, a parasitic inductance 502, a parasitic inductance 503 and a parasitic inductance 512, wherein, the MOSFET 505 can be a power MOSFET. The switching power 500 converts the high DC voltage into low DC voltage by switching on or switching off of the power MOSFET505 and MOSFET 509, wherein, the driving loop 513 comprises the power MOSFET505, the equivalent resistance 506, the parasitic inductance 502 and the control gate 508 and the power stage loop 514 comprises the parasitic inductance 501, the power MOSFET505, the parasitic inductance502, the inductor 504 and the circuit load 515. In the way described above, the internal structure of the switching power is improved by separating the driving loop from the power stage loop, so that the coupling effect at the parasitic inductance 502 shared by the driving loop and the power stage loop is avoided.

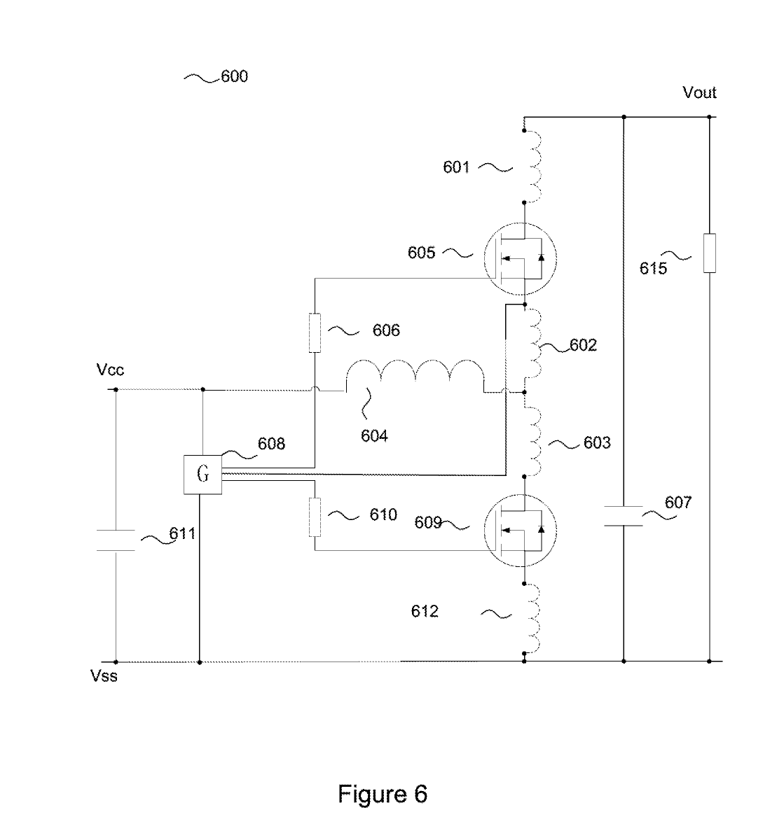

FIG. 6 shows the circuit in a switching power 600 using the power MOSFET chip provided by the present invention. The figure shows the boost mode (the power voltage is lower than the output voltage mode). The power 600 comprises an input capacitor 611, a control gate 608, a MOSFET 605 and a MOSFET 609, an inductor 604, and an output capacitor 607. The figure also shows an equivalent resistance 606 and an equivalent resistance 610, a parasitic inductance601, a parasitic inductance 602, a parasitic inductance 603 and a parasitic inductance 612, wherein, the MOSFET 605 can be a power MOSFET. The switching power 600 converts the high DC voltage into low DC voltage by switching on or switching off of the power MOSFET605 and MOSFET 609, wherein, the driving loop 613 comprises the power MOSFET605, the equivalent resistance 606, the parasitic inductance 602 and the control gate 608 and the power stage loop 614 comprises the parasitic inductance 601, the power MOSFET605, the parasitic inductance602, the inductor 604 and the circuit load 615. As shown in the figure, in the way described above, the internal structure of the switching power is improved by separating the driving loop from the power stage loop, so that the coupling effect at the parasitic inductance 602 shared by the driving loop and the power stage loop is avoided.

Thus, in other chips or circuit structures, if there is coupling effects shared by multiple loops, the structure of the chip or package or the circuit structure can be improved to maintain single point connections of each loop, reducing the shared part of different loops. Because the impedance of the shared part will lead to the mutual coupling and mutual impacts among the different loops. If the different loops are connected by single point connection, the shared reactance is zero, which can significantly reduce the coupling effect.

In summary, the power MOSFET chip provided by the present invention and the switching power using the power MOSFET provided by the present can avoid the coupling effect of the driving loop and the power stage loop at the common source pin, thereby reducing the switching power losses and improving the efficiency of the switching power.

It should be appreciated that various modifications, adaptations and alternative embodiments thereof may be made within the scope and spirit of the present invention. The invention is further defined by the following claims.

What is claimed is:

1. A switching power capable of avoiding coupling effects, the switching power comprising:
a driving loop, wherein, the driving loop comprises:
a substrate end and a gate end of a power Metal-Oxide-Semiconductor Field-Effect Transistor (MOSFET), and
a controlling gate, wherein the controlling gate is connected to the gate end of the power MOSFET and the substrate end of the power MOSFET is connected to the controlling gate.

2. The switching power of claim 1, further comprising a power stage loop, wherein the power stage loop comprises a drain end and a source end of the power MOSFET.

3. The switching power of claim 1, wherein the power MOSFET comprises a plurality of MOSFETs.

4. The switching power of claim 3, wherein the substrate ends of the plurality of MOSFETs are connected and comprise a separate substrate end of the power MOSFET.

5. The switching power of claim 4, wherein the plurality of MOSFETs are connected in parallel.

6. The switching power of claim 5, wherein the number the plurality of MOSFETs is two.

7. The switching power of claim 5, wherein the number the plurality of MOSFETs is three.

8. The switching power of claims 1, wherein a working mode of the switching power is buck mode.

9. The switching power of claims 1, wherein a working mode of the switching power is boost mode.

10. A manufacturing method for a switching power, comprising:
including in a driving loop:
a substrate end and a gate end of a power Metal-Oxide-Semiconductor Field-Effect Transistor (MOSFET), and
a controlling gate;
connecting the controlling gate to the gate end of the power MOSFET; and
connecting the substrate end of the power MOSFET to the controlling gate.

11. The method of claim 10, wherein further included is a power stage loop, wherein the power stage loop comprises the drain end and the source end of the power MOSFET.

12. The method of claim 10, wherein the power MOSFET comprises a plurality of MOSFETs.

13. The method of claim 12, wherein the substrate ends of the plurality of MOSFETs are connected and comprise a separate substrate end of the power MOSFET.

14. The method of claim 13, wherein, the plurality of MOSFETs are connected in parallel.

15. The method of claim 14, wherein the number the plurality of MOSFETs is two.

16. The method of claim 14, wherein the number the plurality of MOSFETs is three.

17. The method of claims 11, wherein a working mode of the switching power is buck mode.

18. The method of claims 11, wherein a working mode of the switching power is boost mode.
